(19) United States
(12) Patent Application Publication
(10) Pub. No.: US 2024/0329401 A1
(43) Pub. Date: Oct. 3, 2024

(54) Display device with multiple microlens layers

(71) Applicant: W GLORY TECHNOLOGY CO., LTD., Hsinchu County (TW)

(72) Inventor: Jih-Fon Huang, Hsinchu County (TW)

(73) Assignee: W GLORY TECHNOLOGY CO., LTD., Hsinchu County (TW)

(21) Appl. No.: 18/504,124

(22) Filed: Nov. 7, 2023

(30) Foreign Application Priority Data
Mar. 31, 2023 (TW) 112112395

(51) Int. Cl. G02B 27/01; H01L 25/075; H01L 33/50; H01L 33/58

(52) U.S. Cl. CPC G02B 27/0172; H01L 25/0753; H01L 33/505; H01L 33/58

(57) ABSTRACT

The invention provides a display device, which comprises a substrate, a luminous layer located on the substrate, the luminous layer defines a plurality of pixel regions, and a first lens layer located on the luminous layer, wherein the first lens layer comprises a plurality of first microlenses, and a second lens layer located on the first lens layer, the second lens layer comprises a plurality of second microlenses, and the size of each second microlens is different from the size of each first microlens.

### BACKGROUND OF THE INVENTION

### 1. Field of the Invention

The present invention relates to the field of displays, in particular to a display device with multilayer microlenses, which can be applied to wearable display devices (such as VR glasses, AR glasses, etc.) and has the effect of reducing the vergence-accommodation conflict (VAC).

### 2. Description of the Prior Art

With the development of technology, in addition to the pursuit of larger display devices, related technologies of virtual reality (VR) or augmented reality (AR) have been gradually applied to existing products, which has led to the development of wearable display devices such as VR glasses or AR glasses.

At present, wearable display devices have always faced a problem, that is, when people look at the objects generated by VR glasses, the distance between the objects displayed by their imaging and the actual screen is different, so they will feel uncomfortable. That is to say, when a person looks at a 3D object displayed on a VR display device, the light emitted on the screen cannot change in depth with the object, so users are prone to feel dizzy and other uncomfortable reactions after using VR glasses for a long time. This phenomenon is also called the vergence-accommodation conflict (VAC), which is commonly referred to as focusing conflict.

Therefore, how to solve the above problems and make wearable display devices with higher quality has become one of the development goals of the industry at present.

### SUMMARY OF THE INVENTION

The invention provides a display device, which comprises a substrate, a luminous layer located on the substrate, wherein the luminous layer defines a plurality of pixel regions, and a first lens layer located on the luminous layer, wherein the first lens layer comprises a plurality of first microlenses, a second lens layer located on the first lens layer, wherein the second lens layer comprises a plurality of second microlenses, and the size of each second microlens is different from the size of each first microlens.

The invention is characterized by providing a display device, which is suitable for a head-mounted electronic display device (such as VR glasses). Unlike the conventional VR glasses, which only include a single microlens layer, the display device of the present invention includes at least two or more microlens layers, the second microlens layer is arranged far away from the light-emitting element. When the light emitted by the light-emitting element passes through the second microlens layer, different light depths can be generated, and the stereoscopic impression of the object viewed by the user is improved. In addition, because the size of each second microlens is quite small (the size is approximately equal to the size of only a few pixel region), it will not cause excessive refraction and distortion of the display screen. The invention has the advantage of improving the quality of the display device.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a schematic diagram of a display device according to a first embodiment of the present invention.

FIG. 2A shows a top view corresponding to the first lens layer and the second lens layer of the present invention.

FIG. 2B is a schematic structural diagram corresponding to the second lens layer of the present invention.

FIG. 3 shows a schematic diagram of a display device according to a second embodiment of the present invention.

FIG. 4 is a schematic diagram of a display device according to a third embodiment of the present invention.

FIG. 5 shows a schematic diagram of a display device according to a fourth embodiment of the present invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

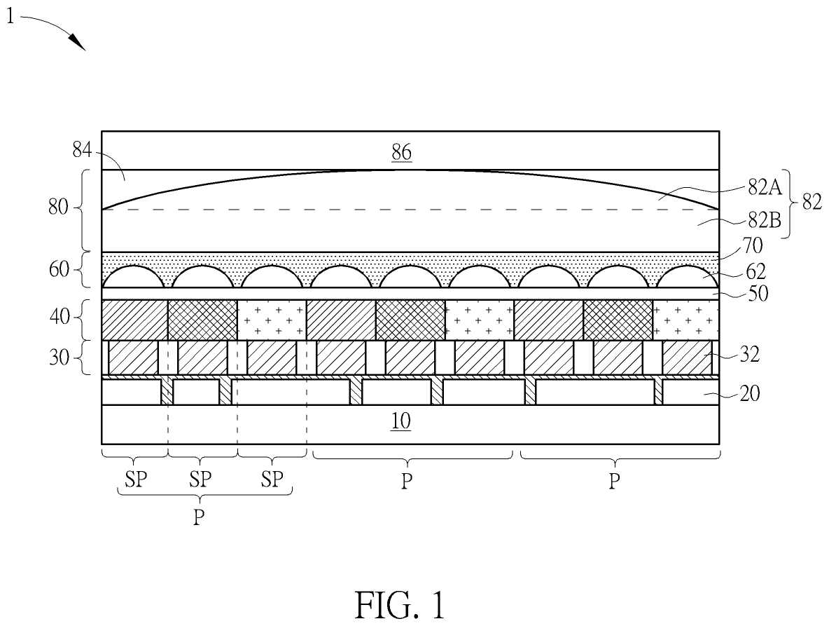

Please refer to FIG. 1, which shows a schematic diagram of a display device according to a first embodiment of the present invention. The display device 1 of the present invention is preferably a wearable display device that can present a 3D picture, such as a display device applied to the virtual reality field such as VR glasses. The following will focus on the display structure of display devices (such as VR glasses).

As shown in FIG. 1, the display device 1 includes a substrate 10, which may include a hard substrate or a flexible substrate, wherein the substrate may include a silicon wafer, a glass substrate, a plastic substrate, a quartz substrate, a sapphire substrate, a polyimide (PI) substrate, a polyethylene terephthalate (PET) substrate, other suitable substrates or their combinations, but not limited to.

Next, a circuit layer 20 and a luminous layer 30 are formed on the substrate 10. The circuit layer 20 may include conductive lines (such as scanning lines, data lines or other conductive lines) and transistors (such as switching elements, driving elements, reset elements and/or compensation elements), but is not limited to this. In addition, the transistor includes structures such as source, drain, gate and channel layer, which belong to the prior art in this field and will not be described in detail here. In addition, the transistor may further include, but is not limited to, a bottom gate transistor, a top gate transistor, a double gate transistor, other suitable transistors or their combinations. The type of transistor and the layout of components can be adjusted as needed.

In addition, the circuit layer 20 comprises conductive materials suitable for forming various conductive elements (including various wires or electrodes such as source, drain and gate in transistors), insulating materials for isolating elements, and semiconductor materials for forming channel layers of transistors. Among them, the conductive material such as metal or transparent conductive material includes indium tin oxide (ITO) or any other suitable conductive material or combination thereof. The insulating material may include, but is not limited to, silicon oxide, silicon nitride, silicon oxynitride, any other suitable insulating material or a combination thereof. The material of the semiconductor may include, but is not limited to, low temperature polycrystalline silicon (LTPS), indium gallium zinc oxide (IGZO), amorphous silicon and/or any other suitable semiconductor material or combination thereof. The various elements in the above circuit layer 20 belong to the conventional technology in the field, and the details of other technologies are not detailed here. In addition, in this embodiment, in order to simplify the drawing, only a single circuit layer 20 is drawn. However, in actual technology, the circuit layer 20 may have a multi-layer structure due to different processes, and this variation is also within the scope of the present invention.

The luminous layer 30 includes a plurality of light-emitting elements 32 for providing the light source of the display device. The light-emitting element 32 may include inorganic light-emitting diode (LED), sub-millimeter light-emitting diode (min-LED), micro-LED, organic light-emitting diode (OLED), any other suitable light-emitting element or their combination, but is not limited to this. This disclosure uses light-emitting diodes (such as submillimeter light-emitting diodes, micro light-emitting diodes or organic light-emitting diodes) as the light-emitting element 32 for example, but the light-emitting element 32 may be other types of light-emitting elements. In addition, each light-emitting element in the luminous layer 30 is electrically connected to various electronic elements such as switching elements or driving elements in the circuit layer 20.

In this embodiment, a color filter layer 40 is located on the luminous layer 30, the color filter layer 40 is used to convert the white light emitted by the light-emitting elements into different colors such as red, green and blue. Or the red, green, blue and other spectra emitted by the luminous layer 30 are purified through the color filter layer. The color filter layer 40 comprises a plurality of different color blocks, and each color block comprises a different color, for example, one of red, green and blue, which can be combined with different colors to achieve a display effect.

In addition, the color filter layer 40 of the present invention may be replaced by other light conversion material layers, such as quantum dots or phosphorescent materials, which have the function of converting the color of light into other colors. In other words, the present invention does not necessarily need to use the color filter layer 40 as a necessary structure. This variation is also within the scope of the present invention.

In this embodiment, the color filter layer 40 may further include a protective layer 50 and a first lens layer 60. The material of the protective layer 50 is, for example, insulating material. The protective layer 50 is used to protect the underlying components, and the first lens layer 60 comprises a plurality of first microlenses 62. It should be noted that in some embodiments, it is also possible to omit the protective layer 50, and this variation also falls within the scope of the present invention.

Here, the invention additionally defines pixel regions (P) and sub-pixel regions (SP). As shown in FIG. 1, a sub-pixel region SP includes a first microlens 62, one color block of the color filter layer 40, a light-emitting element 32 and a set of driving circuits. According to the color difference of the color filter layer 40, the sub-pixel region SP described here comprises different colors, such as red sub-pixel region, blue sub-pixel region and green sub-pixel region. In the present invention, the pixel region P is composed of a plurality of sub-pixel regions SP, for example, one pixel region P may include three sub-pixel regions SP of red, blue and green (R, G and B), but the present invention is not limited to this.

The first lens layer 60 includes a plurality of first microlenses 62, and each first microlens 62 corresponds to a sub-pixel region SP. In the function of the present invention, the first microlens 62 is used to refract and converge the light emitted from the light-emitting element 32, so that the originally divergent light is emitted outward as parallel light, so that the brightness of the display device 1 can be improved.

In the conventional VR display device, only a single-layer microlens group is included, and this single-layer microlens group is used to increase the display brightness corresponding to each sub-pixel. However, because the light emitted from the light-emitting elements of the display device is basically emitted by the light-emitting elements of the same luminous layer, and the distance between the first lens layer and the luminous layer is relatively close, it still faces the problem of vergence-accommodation conflict.

Therefore, in order to reduce the influence of vergence-accommodation conflict, a second lens layer is additionally arranged on the first lens layer to form a light field display effect, so that when a user watches a screen, the light depth between different pixel regions is different, thereby enhancing the stereoscopic impression of the user watching the picture and reducing the discomfort caused by the vergence-accommodation conflict.

In more detail, please continue to refer to FIG. 1. Above the first lens layer 60, it further includes a first flat layer 70, a second lens layer 80, a second flat layer 84 and a transparent protective layer 86. The first flat layer 70 and the second flat layer 84 are, for example, such as polyimide, polycarbonate, acrylate, other suitable materials or their combinations. The function of the first flat layer 70 and the second flat layer 84 is to form a flat surface, so that subsequent devices can be formed on a flat surface. The second lens layer 80 is formed on the first flat layer 70. The second lens layer 80 includes a plurality of second microlenses 82 arranged in an array. For the sake of simplicity, only one second microlens 82 is shown in FIG. 1. The transparent protective layer 86 is made of, for example, glass, and is used to protect the underlying components.

In this embodiment, the second lens layer 80 is farther away from the light-emitting element 32 than the first lens layer 60, and the second lens layer 80 comprises a plurality of second microlenses 82, the shapes and sizes of the second microlenses 82 are different from those of the first microlenses 62. For example, each second microlens 82 of the present invention corresponds to a plurality of pixel regions P (as mentioned above, each pixel region P comprises a plurality of sub-pixel regions SP), so the size of the second microlens 82 is larger than that of the first microlens 62.

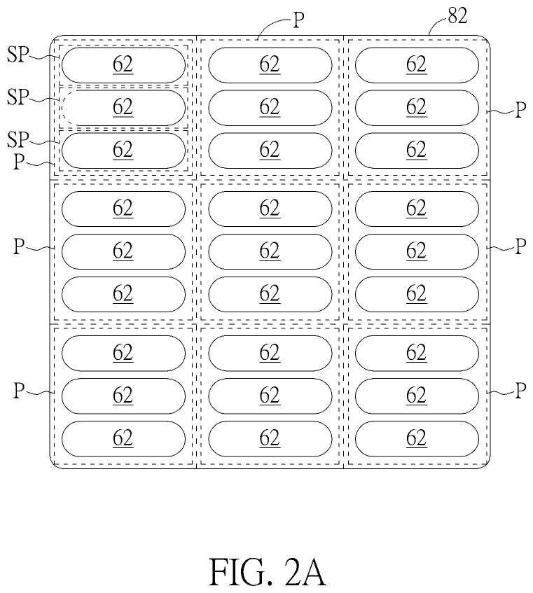

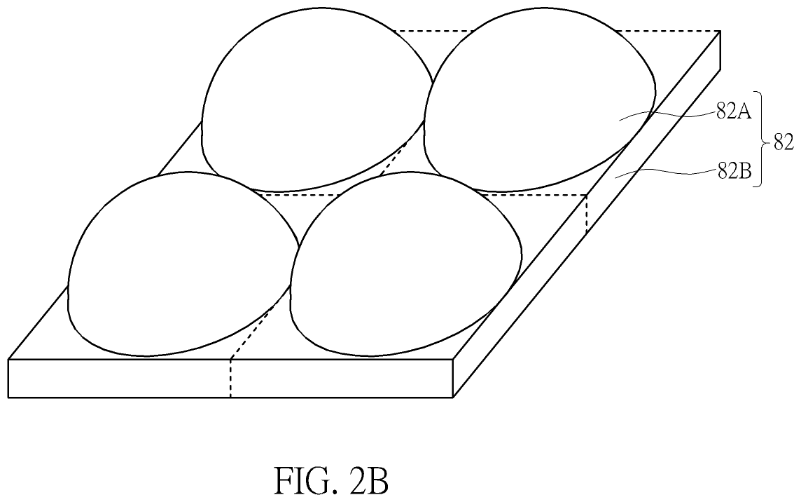

Please refer to FIG. 2A and FIG. 2B together. FIG. 2A shows the top view of the first lens layer and the second lens layer of the present invention, and FIG. 2B shows the structural schematic diagram of the second lens layer of the present invention. For simplicity, FIG. 2A shows only a part of the second lens layer 80 and a part of the corresponding first lens layer 60, while FIG. 2B shows a part of the second lens layer 80. Seen from the top view (FIG. 2A), the lateral dimension of the second microlens 82 is preferably equal to the longitudinal dimension, and the first microlens 62 is, for example, in a strip shape, each first microlens 62 corresponds to a sub-pixel region SP, and three first microlenses 62 (R, G and B of the color filter layer respectively) are combined into a pixel region P. In this embodiment, a single second microlens 82 corresponds to a plurality of first microlenses 62. Taking this embodiment as an example, one horizontal dimension of the second microlens 82 corresponds to three pixel regions (nine sub-pixel regions SP), and the other direction (the longitudinal direction of the vertical plane in FIG. 1 or the longitudinal direction in FIG. 2A) is preferably the same as the horizontal direction. Therefore, in this embodiment, the second microlens 82 corresponds to total 9 pixel regions (e.g., 3×3), and each pixel region P comprises three first microlenses 62, so in this embodiment, one second microlens 82 corresponds to total 27 first microlenses 62. However, it can be understood that the present invention is not limited to this. In other embodiments of the present invention, a second microlens 82 can correspond to, for example, 2×2, 4×4 or other number of pixel regions P, and even a strip-shaped second microlens 82 can be made, so a second microlens 82 can correspond to, for example, 2×3, 4×5 or other number of pixel regions P, which is also within the scope of the present invention.

In addition, from the cross-sectional view (FIG. 1) and 3D view (FIG. 2B), the shape of the second microlens 82 is also different from the shape of the first microlens 62. In detail, the cross-section of the first microlens 62 has a plurality of semi-circular profiles, and the second microlens 82 can be divided into a first part 82A and a second part 82B, the first part 82A has a convex arc profile and the second part 82B has a rectangular profile. That is, a plurality of second microlenses 82 included in the second lens layer 80 are connected to each other by the second portion 82B. In this way, it can avoid the influence of light refraction angle on the picture.

The display device 1 of the present invention can be preferably applied to, for example, VR glasses, and is characterized in that a second microlens 82 is additionally arranged on the first microlens 62, and the second microlens 80 is far away from the first microlens 62. After the light-emitting element 32 emits light, it sequentially passes through the color filter layer 40, the first microlens 62 and the second microlens 82 and enters the user's visual field. Because the second microlens 82 is additionally provided, a part of the light depth can be changed. In other words, from the user's visual field, the depth of light seen from different angles will be slightly different. Compared with the single-layer microlens (the first microlens 62), the user can see a more stereoscopic picture, and compared with the plane light, the invention has more light depth changes, which can also effectively reduce the discomfort caused by the conflict of visual convergence adjustment.

In the following paragraphs, different embodiments of the display device and its manufacturing method of the present invention will be described, and in order to simplify the description, the following description will mainly focus on the differences of each embodiment, and will not repeat the similarities. In addition, the same elements in various embodiments of the present invention are labeled with the same reference numerals, so as to facilitate the comparison among various embodiments.

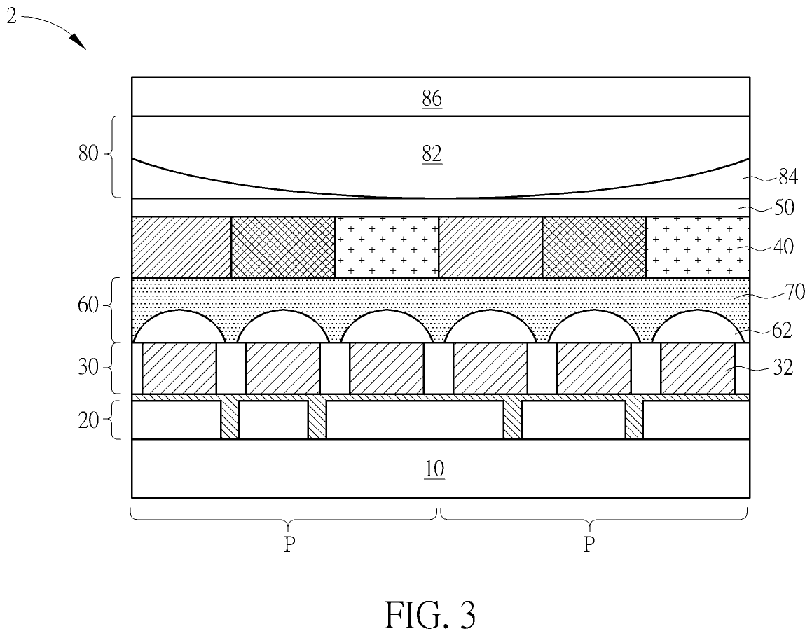

FIG. 3 shows a schematic diagram of a display device according to a second embodiment of the present invention. In this embodiment, most of the elements of the display device 2 are the same as those of the display device 1 described above, and they are not repeated here. However, this embodiment is different from the above-mentioned embodiment in that the direction of the convex surface (i.e., the first part 82A) of the second microlens 82 in this embodiment is different from that described in the above-mentioned first embodiment. The convex surface of the second microlens 82 in this embodiment faces downward, that is, toward the light emitting element 32. In the actual manufacturing process, whether the convex surface of the second microlens 82 faces upward or downward, it can achieve the desired effect of increasing the light depth at different angles in the present invention, so it is within the scope of the present invention to set the second microlens 82 facing upward or downward.

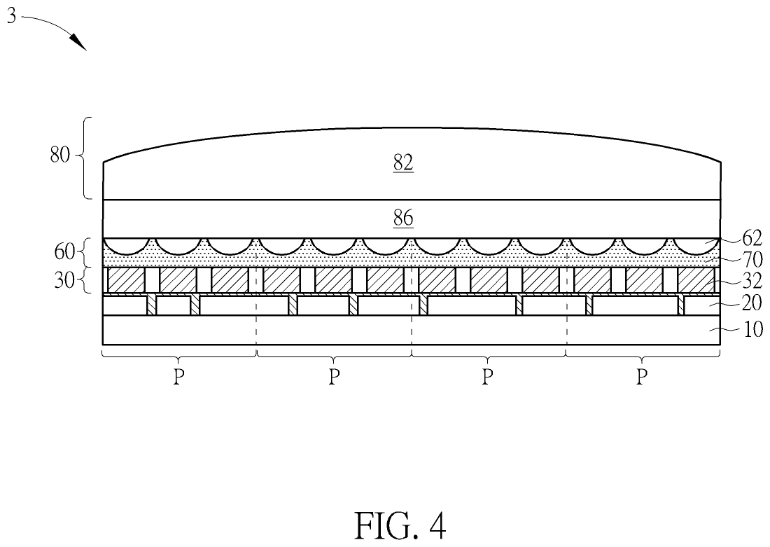

Similarly, FIG. 4 shows a schematic diagram of a display device according to a third embodiment of the present invention. In this embodiment, a display device 3 is provided, which is different from the above embodiment in that the convex surface facing direction of the first microlens 62 can be changed, for example, the convex surface of the first microlens 62 faces downward. The main function of the first microlens 62 is to gather divergent light to enhance brightness, so the same effect can be achieved regardless of whether the convex surface of the first microlens 62 faces upward or downward. Therefore, to sum up, in various embodiments of the present invention, the convex surfaces of the first microlens 62 and the second microlens 82 can be adjusted as required, and the convex surfaces of the first microlens 62 and the second microlens 82 may be arranged in the same direction (both upward or downward), or in different directions (one upward and one downward).

In addition, in FIG. 3 and FIG. 4, the number of pixel regions P corresponding to the second microlens 82 is also different from that in the first embodiment. As mentioned above, the size of the second microlens 82 can be adjusted according to actual needs to correspond to different numbers of pixel regions P. For example, in FIG. 3, the horizontal size of the second microlens 82 corresponds to two pixel regions P, while in FIG. 4, the horizontal size of the second microlens 82 corresponds to four pixel regions P, but the present invention is not limited to this.

In addition, in the present invention, some elements may be omitted. For example, in FIG. 4, the second microlens 82 is arranged on the outermost layer, so it is unnecessary to form a second flat layer to cover the second lens layer 80 (the second microlens 82). In addition, in some embodiments, the transparent protective layer 86 may also be omitted. Alternatively, in some embodiments, the color filter layer 40 may be omitted (e.g., FIG. 4). Combinations of the above-mentioned variations are within the scope of the present invention.

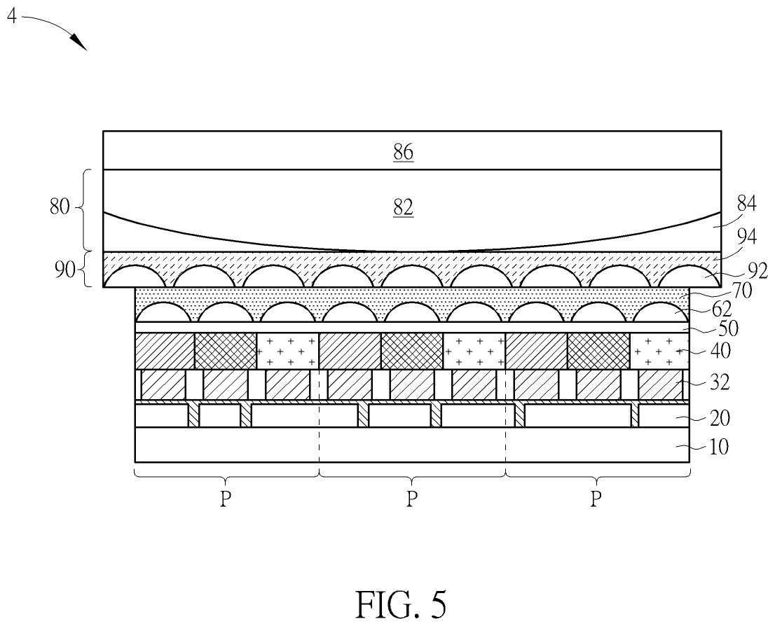

FIG. 5 shows a schematic diagram of a display device according to a fourth embodiment of the present invention. In this embodiment, the display device 4 is provided. In addition to the above-mentioned second lens layer 80 (the second microlens 82), in this embodiment, a third lens layer 90 and a flat layer 94 are additionally added, which is helpful to further increase the variation of light depth. The third lens layer 90 is located between the first lens layer 60 and the second lens layer 80, and includes a plurality of third microlenses 92. In this embodiment, the size of the third microlens 92 may be similar to or slightly different from that of the first microlens 62 (for example, slightly larger than that of the first microlens 62), and the convex direction of the third microlens 92 may be arranged upward or downward as required. In this embodiment, the lateral dimensions of the third lens layer 90 and the second lens layer 80 are slightly larger than those of the first lens layer 60 and other component layers below (such as the circuit layer 20, the luminous layer 30, the color filter layer 40, etc.). In this way, the effect of enlarging the picture can be achieved by using the refraction of light. However, it can be understood that the lateral dimensions of the third lens layer 90 and the second lens layer 80 can also be equal to the dimensions of the first lens layer 60, which is also within the scope of the present invention.

Based on the above description and drawings, the present invention provides a display device, which includes a substrate 10, a luminous layer 30 located on the substrate 10, wherein the luminous layer 30 defines a plurality of pixel regions P, and a first lens layer 60 located on the luminous layer 30, wherein the first lens layer 60 includes a plurality of first microlenses 62, a second lens layer 80 located on the first lens layer 60, wherein the second lens layer 80 includes a plurality of second microlenses 82, and a size of each second microlens 82 is different from a size of each first microlens 62.

In some embodiments of the present invention, the display device 1 is a head mounted display device.

In some embodiments of the present invention, the luminous layer 30 comprises a plurality of light-emitting elements 32, wherein the plurality of light-emitting elements 32 comprise light-emitting diodes.

In some embodiments of the present invention, a circuit layer 20 is further included between the luminous layer 30 and the substrate 10.

In some embodiments of the present invention, a color filter layer is further included, which is located on the luminous layer.

In some embodiments of the present invention, it further includes a plurality of sub-pixel regions SP, each pixel region P is composed of a plurality of sub-pixel regions SP, each first microlens 62 corresponds to a sub-pixel region SP, and each second microlens 82 corresponds to a plurality of pixel regions P.

In some embodiments of the present invention, a flat layer 50 is further included between the first lens layer 60 and the second lens layer 80.

In some embodiments of the present invention, the first microlens 62 and the second microlens 82 each include a convex surface, and the two convex surfaces are arranged in the same direction (for example, both are upward or downward).

In some embodiments of the present invention, the first microlens 62 and the second microlens 82 each include a convex surface, and the convex surfaces are arranged in different directions (e.g., one upward and one downward, or one downward and one upward).

In some embodiments of the present invention, a third lens layer 90 is further included between the first lens layer 60 and the second lens layer 80.

In some embodiments of the present invention, the third lens layer 90 includes a plurality of third microlenses 92, and each third microlens 92 corresponds to a pixel region P.

The invention is characterized by providing a display device, which is suitable for a head-mounted electronic display device (such as VR glasses). Unlike the conventional VR glasses, which only include a single microlens layer, the display device of the present invention includes at least two or more microlens layers, the second microlens layer is arranged far away from the light-emitting element. When the light emitted by the light-emitting element passes through the second microlens layer, different light depths can be generated, and the stereoscopic impression of the object viewed by the user is improved. In addition, because the size of each second microlens is quite small (the size is approximately equal to the size of only a few pixel region), it will not cause excessive refraction and distortion of the display screen. The invention has the advantage of improving the quality of the display device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A display device comprising:
a substrate;
a luminous layer located on the substrate, wherein the luminous layer defines a plurality of pixel regions;
a first lens layer located on the luminous layer, wherein the first lens layer comprises a plurality of first microlenses; and
a second lens layer located on the first lens layer, wherein the second lens layer comprises a plurality of second microlenses, and a size of each second microlens is different from a size of each first microlens.

2. The display device according to claim 1, wherein the display device is a head-mounted display device.

3. The display device according to claim 1, wherein the luminous layer comprises a plurality of light-emitting elements, wherein the light-emitting elements comprise light-emitting diodes.

4. The display device according to claim 1, further comprising a circuit layer located between the luminous layer and the substrate.

5. The display device according to claim 1, further comprising a color filter layer located on the luminous layer.

6. The display device according to claim 1, further comprising a plurality of sub-pixel regions, each of the pixel region is composed of a plurality of sub-pixel regions, and each of the first microlenses corresponds to one sub-pixel region, and each of the second microlenses corresponds to a plurality of sub-pixel regions.

7. The display device according to claim 1, further comprising a flat layer located between the first lens layer and the second lens layer.

8. The display device according to claim 1, wherein the first microlens and the second microlens each comprise a convex surface, and the convex surfaces are arranged in the same direction.

9. The display device according to claim 1, wherein the first microlens and the second microlens each comprise a convex surface, and the convex surfaces are arranged in different directions.

10. The display device according to claim 1, further comprising a third lens layer located between the first lens layer and the second lens layer.

11. The display device according to claim 10, wherein the third lens layer comprises a plurality of third microlenses, and each third microlens corresponds to one pixel region.
